(19) United States
(12) Patent Application Publication
(10) Pub. No.: US 2011/0317714 A1
(43) Pub. Date: Dec. 29, 2011

(54) COMPACT AND ADJUSTABLE POWER DIVIDER AND FILTER DEVICE

(75) Inventors: Santiago SOBRINO ARIAS, MADRID (ES); Isidro HIDALGO CARPINTERO, MADRID (ES); Frederico BRANCA ROCATI, TRES CANTOS (ES)

(73) Assignee: THALES, NEUILLY-SUR-SEINE (FR)

(21) Appl. No.: 12/973,202

(22) Filed: Dec. 20, 2010

(30) Foreign Application Priority Data
Dec. 18, 2009 (EP) 09290971.2

(51) Int. Cl. H04J 99/00; H03H 7/46

(52) U.S. Cl. 370/464; 333/132

(57) ABSTRACT

A power divider and filter device includes one input port and several output ports, and is configured to make several cavities in which resonating posts are located, one post per cavity. The cavities communicate some with the others by means of openings. Cavities are arranged in such a way that and input signal incoming the input port propagates through the device by coupling. The cavities and the resonating posts are configured and arranged in such a way that, as it passes through the device, the input signal is, by one and a same operation, filtered and split in as many output signals as the outputs the device comprises, the energy of the input signal being spread out between the outputs.

### CROSS-REFERENCE TO RELATED APPLICATION

This application claims priority to foreign European patent application No. EP 09290971.2, filed on Dec. 18, 2009, the disclosure of which is incorporated by reference in its entirety.

### FIELD OF THE INVENTION

The invention relates to the field of microwave passive devices. The invention particularly relates to microwave multiplexers and power dividers.

### BACKGROUND OF THE INVENTION

In some telecommunication systems, the received signal contains several communication channels multiplexed in frequency. In order to process each channel separately, receiver equipments generally comprise an Input Multiplexer (IMUX) device. The IMUX device function is to separate each frequency channel included in the input signal and to send each channel to a different output, so the signal corresponding to each of the channels can be processed separately. FIG. 1 shows a typical block diagram of an IMUX device.

Such a microwave device comprises an input channel and several separate output channels each of them consisting in a filter transmitting a signal with a limited bandwidth. Said bandwidth corresponds to that of the communication channel the output channel is supposed to transmit. To this purpose the filter is configured to limit the bandwidth of the input signal to that of the communication channel.

In order to achieve this function the output channels are generally separated in two groups, to minimize interaction between adjacent channels. Each group covers a part of the whole bandwidth of the input signal and the sum of the bandwidths of the two groups is equal the complete bandwidth of the input signal. In most common embodiments, each of the two groups substantially covers a half of the complete bandwidth.

For this purpose IMUX generally comprises a splitting input section comprising a filter associated to a power splitter/divider. The input section filter is intended to match the bandwidth of the input signal, while rejecting useless bands. The filtered input signal is then transmitted to the different communication channels. Such a configuration avoids signals out of the useful band to reach the active equipment, which could reduce the system performance dramatically.

In such an input section, as shown on FIG. 1, the power divider function splits an input signal into two outputs, each one with half the power of the input signal.

Well known microwave structures can be used to achieve this function with minimum power loss due to dissipation and mismatch and with minimum distortion of the input signal. Such a structure generally comprises two separate elements, a filtering element and a power splitting element, connected together by connection means. A drawback of such a configuration is that as the filter element and the splitter element are built and adjusted separately a further adjustment must be done when the two elements are connected together so as to realize the optimal adjustment of the complete structure. This optimal adjustment is important to minimize power loss and distortion of the input signal.

Another drawback of such a structure is that as it is made with two separate elements performing two different functions, the size of the complete structure mainly depends on the size of each element. Consequently, a reduction of the overall size of the structure is possible only if the size of one or of both elements is possible.

Other well known microwave structures can be used to achieve this function with minimum power loss due to dissipation and mismatch and with minimum distortion of the input signal. These structures differ from the aforementioned ones in that they overlap the filtering function and the power dividing function. However, in such structures, the components performing each function are still clearly identifiable.

An example of such a structure is for described in the U.S. Pat. No. 2,823,356 which discloses a device that can be considered as a single device in which the filtering is applied during power division, and not before, like in the aforementioned structures, though it performs the power division and the band selection using different elements for each function (cavity resonators for filtering and a coupler for power division). However, such a structure does have neither the ability of changing the frequency behaviour by tuning adjustments (bandwidth, centre frequency, selectivity, etc.) nor achieving complex responses.

Another example of such a structure is also described in the U.S. Pat. No. 2,735,069 which discloses a device in which power division can be adjusted. However, frequency behaviour of the filtering function is fixed and not adjustable.

### SUMMARY OF THE INVENTION

The invention provides an input section structure making it possible to overcome the drawbacks of the known structures used to make the input section of an Input Multiplexer.

The invention also provides a structure able to combine in one and a same device a filtering and a splitting function. Another object is to provide an integrated signal divider/splitter structure able to produce from an input signal two signals of the same power with a strictly limited bandwidth whatever the bandwidth of the input signal could be. Another object of the invention is to provide an input function that can be controlled for the frequency behaviour as well as for the power balance.

The invention includes a power divider and filter in a single device, including one input and N outputs, and P coupled resonant elements, the device splitting an input signal into N different output signals with a given equal pre-designed and adjustable frequency bandwidth, the power of the input signal being shared between the output signals in a controllable manner.

In an embodiment, the device according to the invention includes a case closed by a cover, said case including an inner space divided into six cavities by internal walls, said cavities communicating with one another by the means of apertures. Each cavity includes a metallic resonating post. One of the posts is configured to receive the input signal, while two other posts are configured to transmit a filtered output signal. The input signal is transmitted from the input to the separate outputs by coupling between the posts. The size and shape of the apertures and the distances between the posts is defined in order to obtain the desired bandwidth for the two output signals as well as to obtain the desired balance of the powers of these output signals.

In an embodiment, the post that is configured to receive the input signal as well as the two posts configured to transmit the two output signals have a parallelepipedic shape, while the other posts have a cylindrical shape.

In another embodiment, the input post and the two output posts are respectively linked to input or output ports.

In yet another embodiment, the cover includes thread holes configured to receive power balance and bandwidth adjustment screws, said holes being arranged on the surface of the cover in order to face the posts or the apertures which separate the different cavities.

The invention also provides a multiplexer device configured to split a signal received on an input port into several output signals each of them being transmitted to a separate output port, each output signal having a given bandwidth and a power level corresponding to a given part of the input signal power level. According to the invention, as its output ports are gathered in two sets, the multiplexer device comprises a power divider and filter device according to the invention which inputs are connected to the input of the multiplexer device, each of the two output signals produced by the power divider and filter device being transmitted to one of the two sets of output ports.

### BRIEF DESCRIPTION OF THE DRAWINGS

The characteristics and advantages of the invention will be better appreciated from the following description, which explains the invention through particular embodiments thereof taken as non limiting examples and which are based on the appended figures, which represent:

FIG. 1, a schematic diagram of an input multiplexer commonly used in a telecommunication system:

FIG. 2, an overview of a first example of input device commonly used to feed an IMUX;

FIG. 3, an overview of a second example of input device commonly used to feed an IMUX;

FIG. 4, a schematic diagram illustrating the operating concept of the invention;

FIG. 5, a schematic diagram illustrating the general operating principle of an input section according to the invention;

FIG. 6, a simplified extended view of the main part of the device according to one embodiment of the invention;

FIG. 7, a view of the equivalent circuit network corresponding to the particular embodiment of FIG. 6; and

FIG. 8, a blow-up overall view of the input device according to the invention.

### DETAILED DESCRIPTION

The input section device according to the invention is an improvement to current input sections. As stated above, current input sections use different elements to realize the two different functions of an input section.

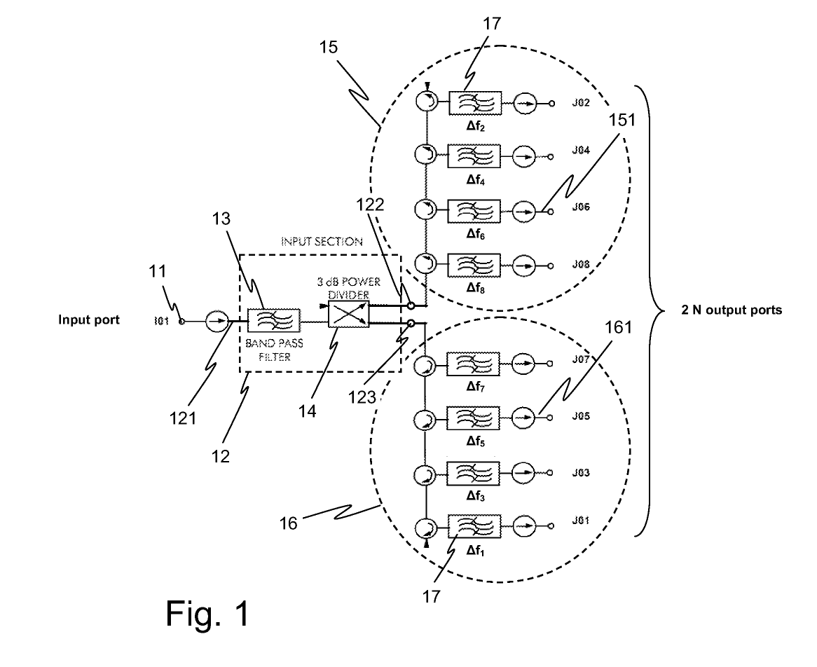

FIG. 1 illustrates the functional diagram of an input multiplexer, IMUX, commonly used in telecommunication equipments (receivers). Such a device mainly comprises two parts, an input part consisting in the input section 12 which comprises an input port 121 and two output ports, 122 and 123, and an output part comprising two separate sets 15 and 16 of output channels.

Each set of output channels 15 or 16 comprises itself an input port connected to one of the two output ports, 122 or 123, of the input section 12 and N output ports, 151 or 161, each port corresponding to one of the output channels of the IMUX device. The example of FIG. 1 shows an IMUX device with two sets of output channels each of them comprising N=4 channels.

Each output channel of an IMUX mainly comprises a band pass filter 17 the bandwidth of which corresponding to the bandwidth of one the communication channels. Moreover the bandwidths of the filters, Δf₁ to Δf₈ in the example, are generally configured so as to cover the whole communication bandwidth ΔF.

According to the prior art illustrated by FIG. 1, the input section 12 mainly comprises an input two separate elements, a band pass filter 13 followed by a power splitter/divider 14. The band pass filter 13 is configured so as to match the whole communication bandwidth and strongly reject out-of-band signals. The power divider 14 generally shares out the input signal received by the input section in output signal, generally of the same power, each signal being sent to one of the two output ports of the section 12.

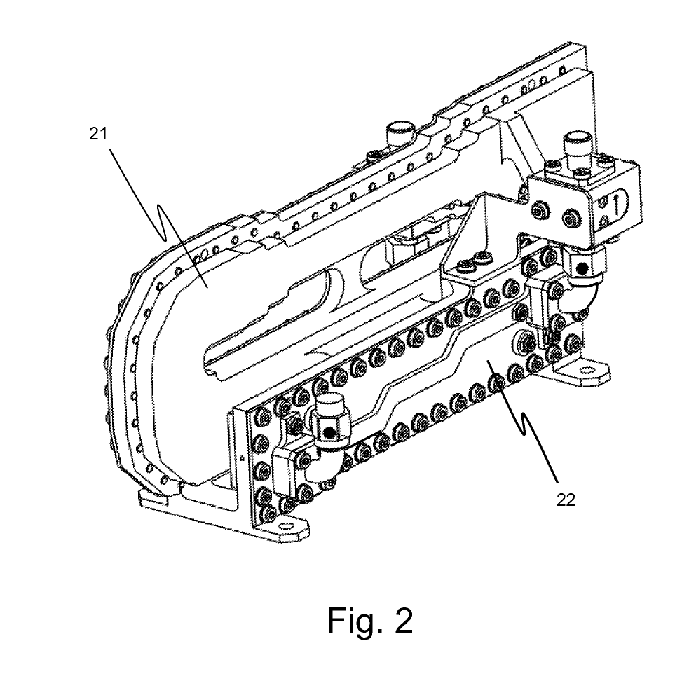

FIG. 2, illustrates a first example of device known of the prior art, achieving the input section function 12. In this example, the input section has wave guide structure comprising two separate coupled devices 21 and 22 in one and a same embodiment.

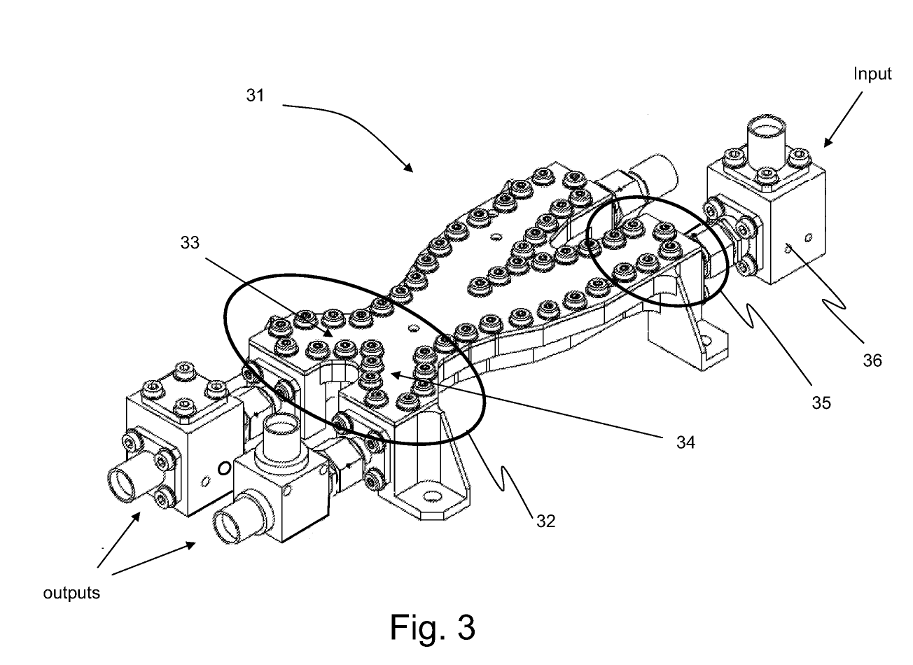

FIG. 3, illustrates a second example of device known of the prior art. In this second example, the input section has a planar structure comprising two separate devices in one and a same embodiment. Said structure comprises a power divider main element 31, with a terminal part 32 corresponding to the two output ports 33 and 34 of the main element 31. The main element 31 has an initial part 35 where the input port 36 is connected, this port comprising a band pass filter at its beginning.

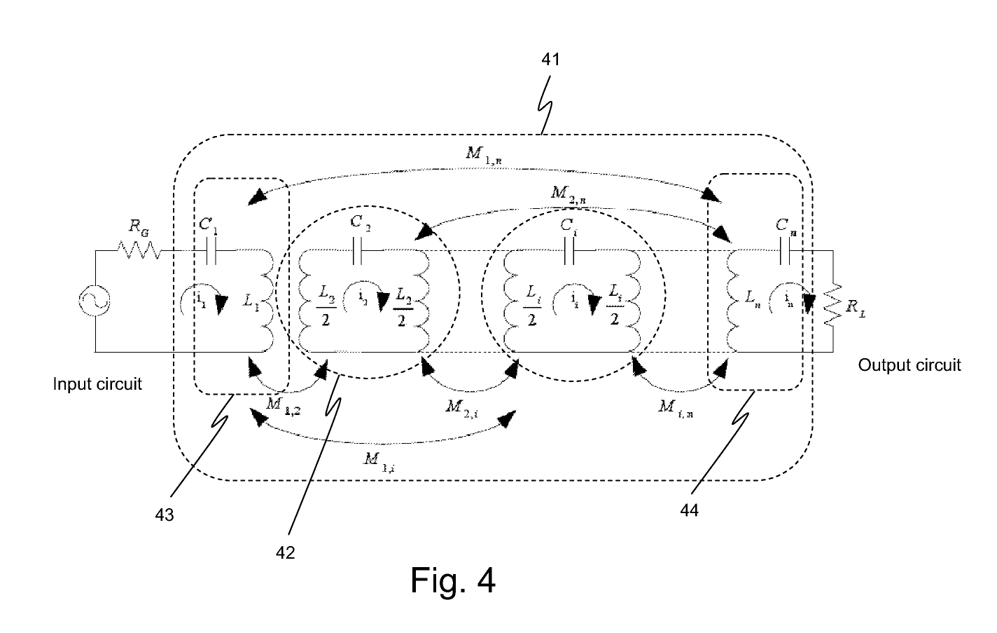

It can be noticed that these two structures correspond to two different possible embodiments of an input section structure, each of them having its advantages and its drawbacks. However, as stated before, and as it can be noticed from FIGS. 3 and 4, both of the structures share the same drawback of achieving the splitting and filtering functions separately, function being implemented after the other.

FIG. 4 shows a schematic diagram illustrating the operating concept of the invention.

The main functional principles of the invention are based on the known methods for microwave filters design. Microwave filters are 2-port devices that show a frequency response according to some electrical requirements. Design methods generally take those requirements and construct an ideal mathematical response (typically a Chebyshev response) that corresponds to them. This ideal mathematical response can be then materialized by an electrical circuit with lumped components, based on resonators and couplers as illustrated on FIG. 4.

The use of known synthesis methods makes it possible to design an equivalent electrical network whose response better fits the mathematical ideal curve. It is thus possible to approximate the desired response by building a microwave structure that has the resonance and coupling characteristics of the ideal equivalent circuit.

As illustrated, the so designed circuit 41 comprises resonators elements 42, 43 and 44 coupled by positive or negative couplings to one another. Microwave resonators can be built using any existing known technology (coaxial resonators, cavity resonators, dielectric resonators . . . ). Input and output circuits are as for them coupled to the device by some resonators 43 and 44 called port resonators.

Other resonators 42, coupled to the port resonators 43 and 44 and coupled to one another, divide the electromagnetic energy produced by the input circuit illustrated by a generator e_{G} and a resistor R_{G} on FIG. 4, and transmit it to the output circuit illustrated by a resistor R_{L}. The frequency response of the device is given by its topology and depends on the coupling matrix of the equivalent electrical network.

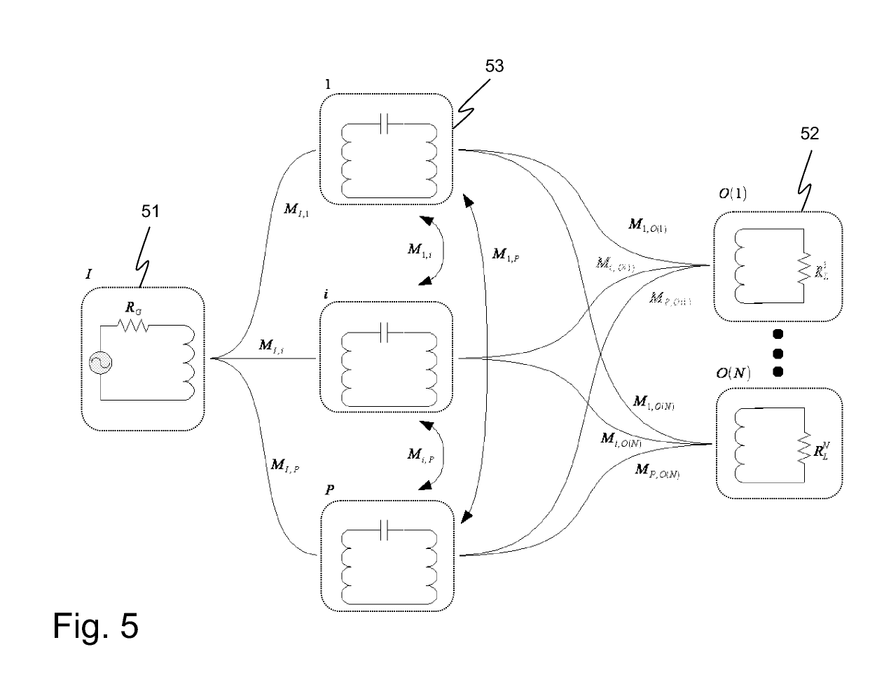

The same concept could be extended to more general networks like the circuit shown in FIG. 5, which illustrates the behaviour of a general input section with one input 51, N outputs 52 and P coupled resonating elements 53, where both input and output ports can be connected/coupled to one or more resonating elements.

Since the equivalent electrical circuit is defined, an analysis of the physical dimensions that determine the electrical properties of the microwave structure elements corresponding to those of the equivalent electrical circuit can be performed. This analysis can be done using any adequate known method. Such analysis advantageously makes it possible to relate the physical dimensions of the microwave structure elements used to build the desired device to the values of the corresponding elements of the equivalent electrical circuit. The structure so established can moreover be tested in an electromagnetic simulator and optimized the values of the different elements to match at best the desired characteristics.

Using such methods it is thus possible to build up a device as a circuit comprising lumped elements. This makes it possible to design a device comprising several elements in which interactions M between the different elements 42, 43 or 44 can be controlled separately so as to obtain a compact and efficient device which energy splitting function and filtering function can be easily and accurately adjusted.

Moreover the characteristics of the different elements and their arrangement can be determined in order to build up, as a single device, a device comprising two identical filters with a common input, and two separate outputs, each filter delivering a filtered signal on the corresponding output and processing a signal which energy is equal to a half of the energy of the signal received at the common input.

In must be noted that in such devices different signal paths can be distinguished, those paths sharing a common part near the input of the device. The balance of the power division is thus controlled by modifying the coupling values in the common part, while the shape of the frequency response is controlled by the coupling and resonance values of the whole structure. Thus the achievable frequency response can be made quite complex. It can include transmission nulls for certain frequencies as well as it can reduce signal distortion in the desired frequency band, or even allow breaking the symmetry with respect the central frequency.

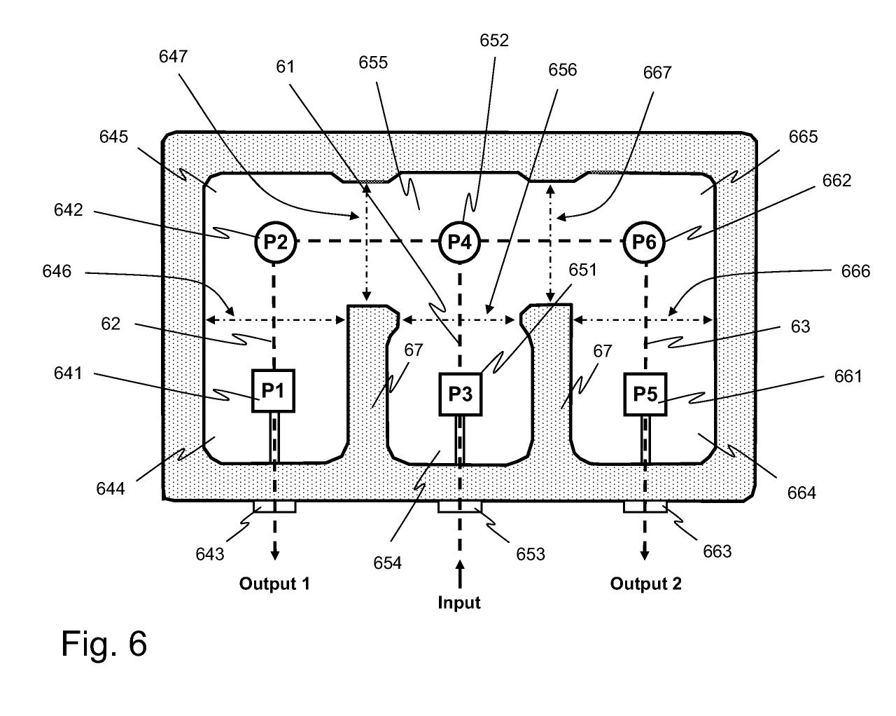

FIG. 6 shows a schematic view of the main structure of the device according to the invention in a particular embodiment given as an example. According to the invention this embodiment corresponds to a device implementing power splitting and frequency filtering in one and a same operation.

The device according to the invention mainly comprises a main metallic cavity 61 partly divided by two internal metallic walls 67 in order to form six cavities 644, 645, 654, 655, 664 and 665. These cavities comprise resonating metallic posts 641, 642, 651, 652, 661 and 662, coupled to one another.

In a preferred embodiment, metallic posts 641, 651 or 661 are connected to coaxial input/outputs 643, 653 and 663 of the device and have a parallelepiped shape. The other posts 642, 652 and 662 are cylindrical.

According to the invention, the dimensions of the different cavities as well as the sizes of the metallic posts are determined, in a known manner, in relation to the frequency and the input power of the signal. As stated before, these determinations can be made using the methods aforementioned. In the other hand the distances between the different posts, as well as the sizes of the apertures between the posts, control the coupling between posts.

According to the invention too, the resonant post 651 is connected to the input signal by connection means providing a coaxial input 653. Similarly, lateral resonant posts 641 and 661 provide each an output filtered signal which energy is of a half of that of the input signal. Output signals are delivered by the means of coaxial connection 643 and 663.

Thus, an incoming signal propagates from the input coaxial line to the inner part of the filter through the first resonating post 651 which transmits it to resonating post 652, being the distance between both posts and the width of the aperture 656 the mechanism used to control the bandwidth. Then, the signal transmitted by post 652 is split up into two parts, each part being transmitted to one of the two resonating posts 642 and 662, so defining two separate paths. The balance of the division is here controlled by apertures 647 and 667 that also match the desired bandwidth. Finally signal passes from posts 642 and 662 to the two output resonating posts 641 and 661. Here, distance is also the mechanism controlling the bandwidth.

Thus, according to the invention, the desired bandwidth of the device is obtained by controlling the distance between the posts located in each of the cavities and the sizes of the apertures 656, 647 and 667 between the cavities. Additionally, the balance of the power splitting of the input signal is achieved by controlling the sizes of the apertures 647 and 667 between cavities 645 and 665.

In such a structure, the metallic posts resonate by themselves, storing and relaxing the electromagnetic energy contained in the communication signal as it flows through the device. The electromagnetic energy is thus propagated between posts directly, using the distance between posts and the widths of the apertures 656, 647 and 667 to control the strength of the coupling. Cylindrical posts 642, 652 or 662 constitute inner resonators, while post 651 constitutes the input resonator that introduces the signal inside the device, and while posts 641 and 661 constitute the output resonators that transmit the propagating signal to the outputs 643 and 663 of the device. The propagation pathways are illustrated by the three doted lines 61, 62 and 63 shown on FIG. 6.

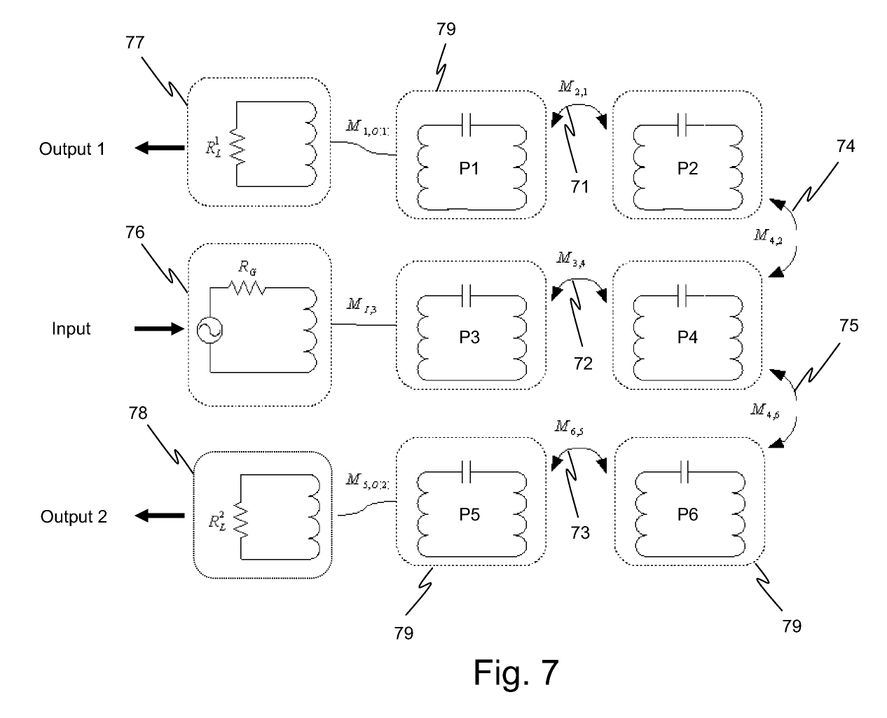

FIG. 7 shows the equivalent circuit network of the particular embodiment of FIG. 6. On this figure each of the posts is figured as a resonant circuit 79 and the couplings between the posts are figured by double curved arrows 71, 72, 73, 74 and 75. Similarly, the input and output ports are figured by L-C circuits 76, 77 and 78.

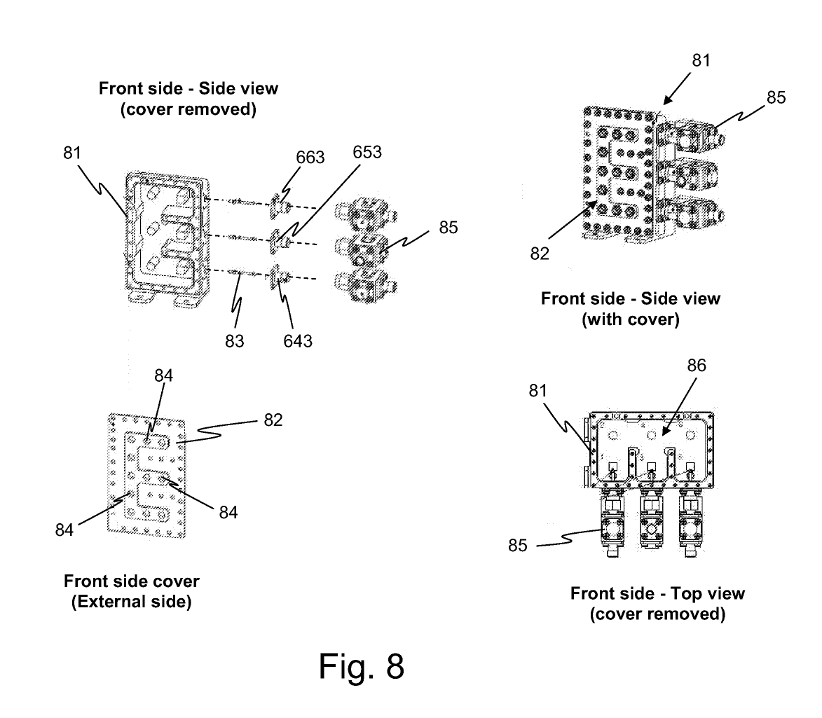

The device according to the invention can be manufactured in different ways. FIG. 8 illustrates a particular embodiment of a device corresponding to the main structure illustrated on FIG. 6.

In this particular embodiment the device is manufactured in metal, aluminium for example. It comprises a body 81 and a cover, or lid, 82. Metallic posts for resonators 641, 651, 661 and 642, 652, 662, and the internal walls 67, are manufactured directly in the body 81 as well as the six cavities 644, 645, 654, 655, 664 and 665, and as the apertures 656, 647 and 667 for couplings.

Input and output ports, 643, 653 and 663, are of the coaxial type, SMA connectors for example, and are directly connected, wired, to the parallelepipedic posts 641, 651 and 661 by means of screwed antennas 83.

Resonator elements take the form of metallic posts 641, 642, 651, 652, 661 and 662. The coupling between resonators is besides performed by the means of apertures 646, 656, 666, 647 and 667 that separate the six cavities.

According to this embodiment, the cover 82 is a plan metallic cover configured so as to be gathered with the body 81, by the means of screws arranged at the periphery of the device for example. Additionally, the cover 82 may also include tuning screws that are provided for filtering function and for power division balance adjustment. These screws are arranged at specific places on the cover, above each resonating post 641, 642, 651, 652, 661 and 662, and above the spaces separating them, making it possible to modify or adjust the behaviour of each resonator and each coupling separately and adjust its characteristics. In a preferred embodiment these screws are assembled on threaded holes 84 machined in the cover 82.

As it can be seen on FIG. 8, the device according to the invention may additionally comprise isolator elements 85 to improve electrical return loss. In the embodiment of FIG. 8 these elements are for example directly connected to input and output ports 643, 653 and 663.

Thus, the device according to the invention, as afore described makes it possible to perform a bandwidth selection and a power division with just one and a same circuit, comprising lumped elements contributing to both filtering and splitting functions. So, it can be advantageously used as the input section circuit of an Input Multiplexer.

Such a device can be advantageously designed using classical filter circuits synthesis techniques and can comprise tuning elements to adjust precisely its frequency response and the power balance ratio. In addition, such a device can be designed in such a way that frequency response can be made arbitrarily complex.

More generally, this structure is applicable to realize any “n ways” power divider, where n is an integer higher than 1. Furthermore, this structure is suitable for building power dividing circuits or devices for which the working frequency bandwidth must be accurately defined and for which minimizing the overall mass and size are that while maintaining maximum performances, is a main target.

What is claimed is:

1. A power divider and filter in a single device, comprising one input and N outputs, and P coupled resonant elements, said device splitting an input signal into N different output signals with a given equal pre-designed and adjustable frequency bandwidth, the power of the input signal being shared between the output signals in a controllable manner.

2. The device as claimed in claim 1, further comprising a case closed by a cover, said case including an inner space divided into six cavities by internal walls, said cavities communicating with one another by the means of apertures, each cavity including a metallic resonating post, one post being configured to receive the input signal, while two other posts are configured to transmit a filtered output signal, the input signal being transmitted from the input to the separate outputs by coupling between the posts, the size and shape of the apertures and the distances between the posts being defined in order to obtain the desired bandwidth for the two output signals as well as to obtain the desired balance of the powers of these output signals.

3. The device according to claim 2, wherein the post is configured to receive the input signal and the two posts configured to transmit the two output signals have a parallelepipedic shape, while the other posts have a cylindrical shape.

4. The device according to claim 2, wherein the input post and the two output posts are respectively linked to input or output ports.

5. The device according to claim 2, wherein the cover comprises thread holes configured to receive power balance and bandwidth adjustment screws, said holes being arranged on the surface of the cover in order to face the posts or the apertures which separate the different cavities.

6. A multiplexer device which splits a signal received on an input port into several output signals, each of which are transmitted to a separate output port, each output signal having a given bandwidth and a power level corresponding to a given part of the input signal power level, the output ports of the multiplexer device being gathered in two sets, said device comprising a power divider and filter device according to claim 1, wherein the input of the power divider and filter device are connected to the input of the multiplexer device, each of the two output signals produced by the power divider and filter device being transmitted to one of the two sets of output ports.

7. The device according to claim 1, comprising at least one of a predetermined element or technology used to implement the resonant elements, a predetermined coupling mechanism, a predetermined technique used to connect the input port and the N output ports to the corresponding port resonators, and a predetermined mechanism used to adjust the frequency bandwidth or the power division.
